(19) United States
(12) Patent Application Publication
(10) Pub. No.: US 2026/0271560 A1
(43) Pub. Date: Sep. 10, 2026

(54) DISPLAY DEVICE AND ELECTRONIC DEVICE INCLUDING THE SAME

(71) Applicant: Samsung Display Co., LTD., Yongin-si (KR)

(72) Inventors: WONSE LEE, Yongin-si (KR); DONGHYEON JANG, Yongin-si (KR)

(21) Appl. No.: 19/369,628

(22) Filed: Oct. 27, 2025

(30) Foreign Application Priority Data
Mar. 5, 2025 (KR) 10-2025-0028445

(51) Int. Cl. H10K 59/131; H10K 102/00

(52) U.S. Cl. CPC H10K 59/131; H10K 2102/311

(57) ABSTRACT

A display device includes: a substrate including a first region, a second region, and a bending region between the first region and the second region, the first region including a display area, in which a plurality of pixels are arranged, and a non-display area, and the second region being spaced from the first region and including a pad area; a plurality of data lines arranged in the display area and transmitting a data signal to the plurality of pixels; a plurality of fan-out wires extending from the pad area to the display area across the bending region and respectively corresponding to the plurality of data lines; and a plurality of power connection wires arranged across the bending region and transmitting power for driving light-emitting elements. The plurality of fan-out wires and the plurality of power connection wires are alternately arranged in the bending region.

### CROSS REFERENCE TO RELATED APPLICATIONS

This application claims priority to Korean Patent Application No. 10-2025-0028445, filed on March 5, 2025, and all the benefits accruing therefrom under 35 U.S.C. §119, the content of which in its entirety is herein incorporated by reference.

### BACKGROUND

### 1. Field

Embodiments of the disclosure relate to a display device and an electronic device including the same.

### 2. Description of the Related Art

Display devices visually display data. These display devices include a substrate divided into a display area and a non-display area. A plurality of pixel areas are defined in the display area. Additionally, the display area is provided with a thin film transistor and a pixel electrode electrically connected to the thin film transistor, in correspondence to each of the pixel areas. The non-display area is provided with various conductive layers such as a wire that transmits electrical signals to the display area.

By bending at least a portion of such a display device, visibility at various angles may be improved, or a non-display area may be reduced. For example, by folding backwards at least a portion of a display panel in a non-display area surrounding a display area of a display device, at least a portion of the non-display area may be positioned at the rear of the display panel. Accordingly, dead space of the display device may be reduced. A bending portion of the display panel is referred to as a bending region.

Additionally, the display device itself is flexible so that the shape of at least a portion of the display device may be changed. Such flexible display devices may be classified into bendable display devices, foldable display devices, rollable display devices, stretchable display devices, etc., depending on their purpose or form.

Electronic devices may provide users with visual interfaces desired by the users through display devices.

### SUMMARY

Embodiments of the disclosure aim to provide a display device with improved luminance deviation and an electronic device including the same. However, these tasks are exemplary, and the scope of the disclosure is not limited thereby.

An embodiment of the disclosure provides a display device including a substrate including a first region, a second region, and a bending region between the first region and the second region, the first region including a display area, in which a plurality of pixels are arranged, and a non-display area surrounding the display area, and the second region being spaced from the first region and including a pad area; a plurality of data lines arranged in the display area and transmitting a data signal to the plurality of pixels; a plurality of fan-out wires extending from the pad area to the display area across the bending region and respectively corresponding to the plurality of data lines; and a plurality of power connection wires arranged across the bending region and transmitting power for driving light-emitting elements of the plurality of pixels, where the plurality of fan-out wires and the plurality of power connection wires are alternately arranged in the bending region.

In an embodiment of the disclosure, the plurality of fan-out wires may be electrically connected to the plurality of data lines, respectively.

In an embodiment of the disclosure, each of the plurality of fan-out wires may include a data supply wire connected to output terminals of a display driving circuit, a data transfer wire connected to one of the data lines of the display area, and a data connection wire electrically connecting the data supply wire to the data transfer wire.

In an embodiment of the disclosure, the data supply wire may be disposed in the second region, and the data transfer wire may be disposed in the first region.

In an embodiment of the disclosure, a plurality of data connection wires respectively included in the plurality of fan-out wires may be arranged alternately with the plurality of power connection wires.

In an embodiment of the disclosure, the data supply wire may be disposed in a different layer than the data connection wire and may at least partially overlap the data connection wire.

In an embodiment of the disclosure, the data supply wire may be electrically connected to the data connection wire through a contact hole defined in an insulating layer disposed on the data supply wire.

In an embodiment of the disclosure, the data transfer wire may be disposed in a different layer than the data connection wire and may at least partially overlap the data connection wire.

In an embodiment of the disclosure, the data transfer wire may be electrically connected to the data connection wire through a contact hole defined in an insulating layer disposed on the data transfer wire.

In an embodiment of the disclosure, the data supply wire and the data transfer wire may be arranged in the same layer.

In an embodiment of the disclosure, the plurality of power connection wires may connect a power input wiring disposed in the second region to a power transfer wiring disposed in the first region.

In an embodiment of the disclosure, the power transfer wiring may include a first bending periphery disposed along a first direction corresponding to a bending axis of the substrate, the power input wiring may include a second bending periphery disposed along the first direction, an end of each of the plurality of power connection wires may be connected to the first bending periphery, and an opposite end of each of the plurality of power connection wires may be connected to the second bending periphery.

In an embodiment of the disclosure, the power input wiring may be disposed on the data supply wire.

In an embodiment of the disclosure, the power transfer wiring may be disposed on the data transfer wire.

In an embodiment of the disclosure, the data connection wire may be disposed in the same layer as the plurality of power connection wires.

In an embodiment of the disclosure, the plurality of power connection wires and the data connection wire may be arranged on a first flattening layer, and a second flattening layer may be disposed on the plurality of power connection wires and the data connection wire.

In an embodiment of the disclosure, the data supply wire may include a first data supply wire transmitting a first data signal and a second data supply wire transmitting a second data signal.

In an embodiment of the disclosure, the first data supply wire and the second data supply wire may be arranged in different layers from each other.

An embodiment of the disclosure provides an electronic device including a processor, a memory storing input data used by the processor or output data, a display module configured to implement one or more images under control by the processor, and a power module configured to provide power to the processor, the memory and the display module, where the display module includes a substrate including a first region, a second region, and a bending region between the first region and the second region, the first region including a display area, in which a plurality of pixels are arranged, and a non-display area surrounding the display area, and the second region being spaced from the first region and including a pad area; a plurality of data lines arranged in the display area and transmitting a data signal to the plurality of pixels; a plurality of fan-out wires extending from the pad area to the display area across the bending region and respectively corresponding to the plurality of data lines; and a plurality of power connection wires arranged across the bending region and transmitting power for driving light-emitting elements of the plurality of pixels, where the plurality of fan-out wires and the plurality of power connection wires are alternately arranged in the bending region.

In an embodiment of the disclosure, each of the plurality of fan-out wires may include a data supply wire connected to output terminals of a display driving circuit, a data transfer wire connected to one of the data lines of the display area, and a data connection wire electrically connecting the data supply wire to the data transfer wire.

### BRIEF DESCRIPTION OF THE DRAWINGS

The above and other features and advantages of illustrative embodiments of the disclosure will be more apparent from the following description taken in conjunction with the accompanying drawings in which:

FIG. 1 is a schematic perspective view illustrating an embodiment of a display device according to the disclosure;

FIG. 2 is a plan view showing the display device of FIG. 1;

FIG. 3 is a cross-sectional view showing a bent state of the display device of FIG. 1;

FIG. 4 is a schematic circuit diagram illustrating an embodiment of a display element provided in a pixel of a display device and a pixel circuit connected to the display element, according to the disclosure;

FIG. 5 is a schematic cross-sectional view illustrating an embodiment of a cross-section taken along line I-I' in FIG. 2;

FIG. 6 is a schematic cross-sectional view illustrating an embodiment of an electronic panel according to the disclosure;

FIG. 7 is an enlarged conceptual diagram of a region A in FIG. 2;

FIG. 8 is an enlarged conceptual diagram of a region B in FIG. 7;

FIG. 9 is a schematic cross-sectional view illustrating an embodiment of a cross-section taken along line II-II' in FIG. 8;

FIG. 10 is a schematic cross-sectional view illustrating an embodiment of a cross-section taken along line III-III' in FIG. 8;

FIG. 11 is a schematic cross-sectional view illustrating an embodiment of a cross-section taken along line IV-IV' in FIG. 8;

FIG. 12 is a schematic cross-sectional view illustrating another embodiment of the cross-section taken along line IV-IV' in FIG. 8;

FIG. 13 is a block diagram of an embodiment of an electronic device; and

FIG. 14 is a schematic diagram of embodiments of electronic devices.

### DETAILED DESCRIPTION

The disclosure may undergo various modifications and have various embodiments, and illustrative embodiments are illustrated in the drawings and described in detail in the detailed description. The effects and features of the disclosure and the method for achieving them will become clear with reference to the embodiments described in detail below together with the drawings. However, the disclosure is not limited to the embodiments disclosed below and may be implemented in various forms.

In the embodiments below, the terms "first," "second, etc., are not used in a limiting sense but are used to distinguish one component from another.

In the embodiments below, singular expressions include plural expressions unless the context clearly indicates otherwise.

In the embodiments below, terms such as “include” or “have” specify the presence of stated features or components, but do not preclude the presence or addition of one or more other features or components.

In the embodiments below, when it is said that a part, such as a unit, region, or component, is disposed above or on another part, this includes not only the case where it is directly above the other part but also the case where another unit, region, component, etc., is interposed in between.

In the embodiments below, terms, such as "connect" or "combine", do not necessarily imply a direct and/or fixed connection or combination of two members, unless the context clearly indicates otherwise, and do not exclude the presence of another member between the two members.

In the drawings, the sizes of components may be exaggerated or reduced for convenience of explanation. For example, the sizes and/or thicknesses of components in the drawings are arbitrarily shown for convenience of explanation, and therefore, the disclosure is not necessarily limited thereto.

In this specification, that a region or portion corresponds to another region or portion means that regions or portions overlap each other and are not limited to having the same area and/or the same shape.

Hereinafter, embodiments of the disclosure will be described in detail with reference to the attached drawings. In the drawings, identical or corresponding components are given the same reference numerals, and redundant descriptions thereof will be omitted.

Hereinafter, the disclosure will be described in detail with reference to embodiments of the disclosure illustrated in the attached drawings.

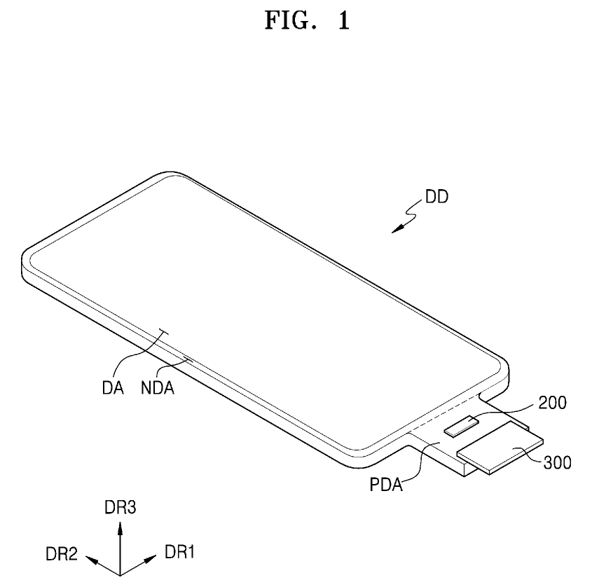

FIG. 1 is a schematic perspective view illustrating an embodiment of a display device according to the disclosure.

Referring to FIG. 1, in an embodiment of according to the disclosure, a display device DD may be activated according to an electrical signal. Although it is illustrated in FIG. 1 that the display device DD is a mobile phone, the spirit of the disclosure is not limited thereto.

In an embodiment of the disclosure, the display device DD may include a display surface defined by a first direction DR1 and a second direction DR2 crossing the first direction DR1. Images generated in the display device DD may be provided to a user through a display surface.

Hereinafter, a direction substantially perpendicular to the plane defined by the first direction DR1 and the second direction DR2 is defined as a third direction DR3. The third direction DR3 is a standard for distinguishing the front (top) and the back (bottom) of each component. In this specification, “in a plan view” may be defined as a state viewed in the third direction DR3.

In an embodiment, the display device DD may include a display area DA and a non-display area NDA outside the display area DA. Although it is illustrated in FIG. 1 that the display area DA has a substantially quadrangular shape, e.g., substantially rectangular shape, the disclosure is not limited thereto. The display area DA may be provided in various shapes, such as a circular shape, an elliptical shape, and a polygonal shape.

The display area DA is a part that displays an image, and a plurality of pixels PX may be arranged in the display area DA. Hereinafter, a "pixel" used herein may refer to a "sub-pixel." Each pixel PX may include a light-emitting element, such as an organic light-emitting diode. In an embodiment, each pixel PX may emit light of red, green, blue, or white, for example.

The display area DA may provide a predetermined image through light emitted from the pixels PX. As used herein, a pixel PX may be defined as a light-emitting region that emits light of any one of red, green, blue, and white, as described above.

The non-display area NDA may be an area, in which the pixels PX are not arranged, and may not provide an image. The non-display area NDA may include a printed circuit board, which includes a power supply wire and a driving circuit to drive the pixels PX, or a terminal, to which a driver integrated circuit (“IC”) is connected.

Hereinafter, an organic light-emitting display device is described in an embodiment of the display device DD according to the disclosure. However, the display device DD in the disclosure is not limited thereto. In an embodiment, the display device DD may include an inorganic light-emitting display (or an inorganic electroluminescent (“EL”) display) or a quantum dot light-emitting display. In an embodiment, a light-emitting layer included in a light-emitting element of the display device DD may include an organic material or an inorganic material, for example. A quantum dot may be disposed on a path of light emitted from the light-emitting layer.

In an embodiment of the disclosure, the display device DD may be applied to various products, e.g., televisions, laptops, monitors, billboards, Internet of Things (“IoT”) devices, and portable electronic devices, such as mobile phones, smart phones, tablet personal computers, mobile communication terminals, electronic notebooks, electronic books, portable multimedia players (“PMPs”), navigation devices, and ultra mobile personal computers (“UMPCs”). In an embodiment, the display device DD may also be applied to wearable devices, such as a smart watch, a watch phone, a glasses-type display, and a head mounted display (“HMD”). In an embodiment, the display device DD may also be applied to a car instrument panel, a center information display (“CID”) placed on a center fascia or a dashboard of a car, a room mirror display replacing a side-view mirror of a car, and a display screen placed on the back of a front seat as entertainment for the rear seat of a car.

Although not shown, the display device DD may include a fold region and a plurality of non-fold regions. In an embodiment, the display device DD may have a fold region between non-fold regions, for example. That is, the display device DD may be folded so that non-fold regions face each other, and a display surface may be inner-folded so as not to be exposed to the outside. In an alternative embodiment, the display surface may be outer-folded so as to be exposed to the outside.

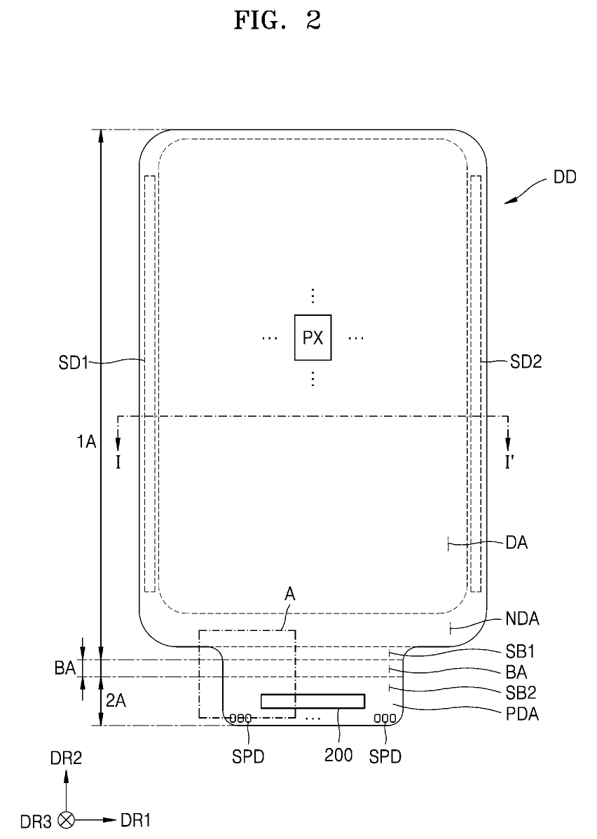

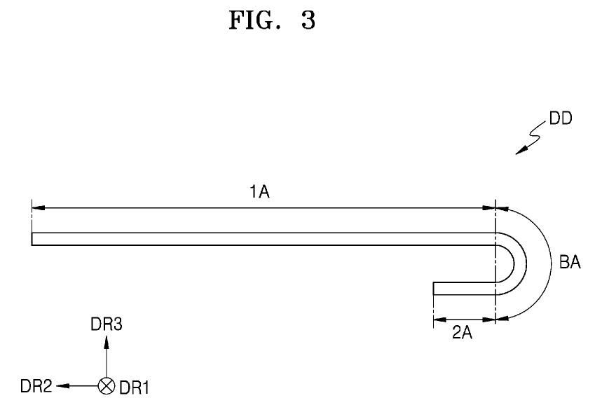

FIG. 2 is a plan view showing the display device DD of FIG. 1. FIG. 3 is a cross-sectional view showing a bent state of the display device DD of FIG. 1.

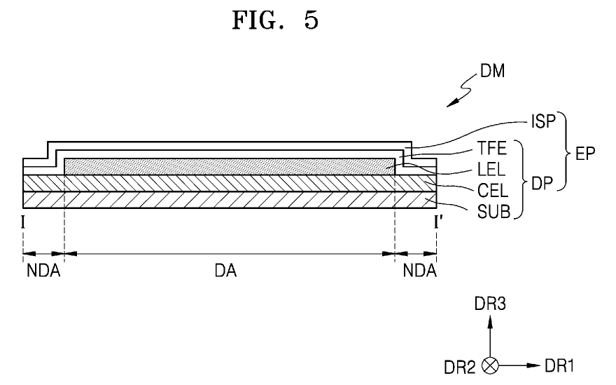

A display panel DP (refer to FIG. 5) may include a display area DA capable of displaying an image and a non-display area NDA around the display area DA. Here, the display area DA and the non-display area NDA may respectively correspond to the display area DA and the non-display area NDA of the display device DD (refer to FIG. 1).

The display panel DP may include a bending region BA and a first region 1A and a second region 2A, which are respectively at opposite sides of the bending region BA.

To explain this from another perspective, the display panel DP may include the bending region BA between the first region 1A and the second region 2A.

The display area DA is disposed in the first region 1A. The second region 2A may be spaced apart from the first region 1A.

The display panel DP may be bent in the bending region BA. The bending region BA may be bent about a bending axis that is parallel to the first direction DR1. In a state where the display panel DP is bent, the first region 1A and the second region 2A may face each other and overlap in the third direction DR3 that is perpendicular to a plane on which the first direction DR1 crosses the second direction DR2, as illustrated in FIG. 3.

In an embodiment, the non-display area NDA may include the bending region BA between a pad area PDA and the display area DA, for example. In this case, a substrate SUB (refer to FIG. 5) may be bent in the bending region BA such that the first region 1A at one side of the bending region BA and the second region 2A at an opposite side overlap each other. In an embodiment, the substrate SUB may be bent in the bending region BA such that at least a portion of the pad area PDA overlaps the display area DA, for example. In this case, the bending direction may be set such that the pad area PDA does not cover the display area DA and is disposed behind the display area DA. Accordingly, a user may perceive that the display area DA occupies most of the display device DD.

A display driving circuit 200 to be described below is disposed (e.g., mounted) on the same surface as the display surface of the display area DA, but as the display panel DP is bent in the bending region BA, the display driving circuit 200 may be disposed on the back of the display area DA.

The display device DD may include the display panel DP, the display driving circuit 200, and a circuit board 300.

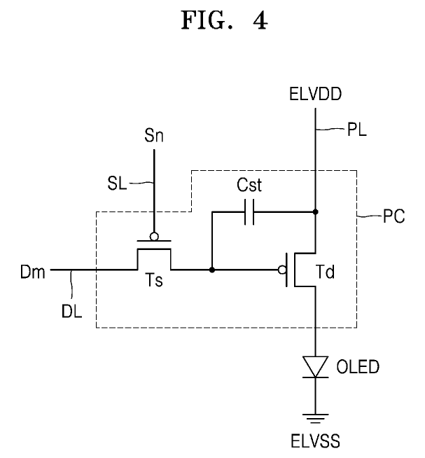

The display driving circuit 200 may be disposed in the pad area PDA of the substrate SUB and may provide data driving signals to data lines DL (refer to FIG. 4).

The display driving circuit 200 may be provided as an IC and may be disposed (e.g., mounted) on the pad area PDA of the substrate SUB by a chip-on-glass (“COG”) method, a chip-on-plastic (“COP”) method, or an ultrasonic bonding method. However, this is merely one of embodiments, and the arrangement of the display driving circuit 200 is not limited to that illustrated in FIG. 2.

In an embodiment, the display driving circuit 200 may be attached to the circuit board 300 by a chip-on-film (“COF”) method, for example. The circuit board 300 may be electrically connected and attached to signal pads SPD of a pad area (“PDA”) by a low-resistance, high-reliability material, such as anisotropic conductive film. Pixel circuits PC (refer to FIG. 4) in the display area DA and the display driving circuit 200 may receive digital video data, timing signals, and driving voltages from the circuit board 300. The circuit board 300 may include a flexible printed circuit board, a printed circuit board, or a flexible film such as a COF. The circuit board 300 may be bonded to the signal pads SPD (in FIG. 2) in the pad area PDA of the substrate SUB.

A first scan driving circuit SD1, a second scan driving circuit SD2, and a common voltage supply wire (not shown) may be arranged in the non-display area NDA.

The first scan driving circuit SD1 may extend along the edge of the substrate SUB. This first scan driving circuit SD1 may provide scan signals to pixels through scan lines (not shown) extending into the display area DA in the first direction DR1. The second scan driving circuit SD2 may be disposed symmetrically to the first scan driving circuit SD1 with the display area DA therebetween. Some of the pixels arranged in the display area DA may be electrically connected to the first scan driving circuit SD1, and remaining (the other) pixels may be electrically connected to the second scan driving circuit SD2. When desired, the second scan driving circuit SD2 may be omitted, and all pixels arranged in the display area DA may be electrically connected to the first scan driving circuit SD1.

A light emission control driving circuit (not shown) or the like may be disposed on the side of the first scan driving circuit SD1 or the second scan driving circuit SD2, and light emission control signals or the like may be provided to a pixel through a light emission control line (not shown) or the like that is substantially parallel to the scan lines.

A plurality of signal pads SPD may be arranged in the pad area PDA of a display panel DP. The signal pads SPD may be exposed without being covered by an insulating layer and may be electrically connected to a printed circuit board (not shown). That is, pads of the printed circuit board may be electrically connected to the signal pads SPD of the display panel DP.

The printed circuit board may transmit signals or power from a control unit to the display panel DP. A control signal generated by the control unit may be transmitted to the display driving circuit 200, the first scan driving circuit SD1, the second scan driving circuit SD2, etc., through the printed circuit board. The control unit may provide a common voltage (e.g., ELVSS in FIG. 4) to the common voltage supply wire and a driving voltage (e.g., ELVDD in FIG. 4) to a driving power wire (not shown) extending into the display area DA in the second direction DR2. The detailed descriptions thereof are given below. Here, the common voltage supply wire may have a shape that partially surrounds the display area DA.

The control unit may generate a data signal, and the data signal may be transmitted to a pixel through the display driving circuit 200 and the data line DL.

In an embodiment of the disclosure, the display device DD may include a bending protection layer (not shown) on an upper surface that is one surface of the display panel DP. The bending protection layer may overlap the bending region BA and a portion of the first region 1A around the bending region BA. The bending protection layer may also overlap a portion of the second region 2A around the bending region BA.

FIG. 4 is a schematic circuit diagram illustrating an embodiment of a display element provided in a pixel of a display device and a pixel circuit connected to the display element, according to the disclosure.

Referring to FIG. 4, a pixel PX may include a pixel circuit PC, which is connected to a scan line SL and a data line DL, and an organic light-emitting element OLED connected to the pixel circuit PC.

The pixel circuit PC may include a driving thin film transistor Td, a switching thin film transistor Ts, and a storage capacitor Cst. The switching thin film transistor Ts may be connected to the scan line SL and the data line DL and may transmit a data signal Dm, which is input through the data line DL, to the driving thin film transistor Td according to a scan signal Sn input through the scan line SL.

The storage capacitor Cst may be connected to the switching thin film transistor Ts and a driving voltage line PL and may store a voltage corresponding to the difference between a voltage received from the switching thin film transistor Ts and a driving voltage ELVDD or a first power supply voltage, each supplied to the driving voltage line PL.

The driving thin film transistor Td may be connected to the driving voltage line PL and the storage capacitor Cst and may control a driving current flowing to the organic light-emitting element OLED from the driving voltage line PL in response to the value of the voltage stored in the storage capacitor Cst. The organic light-emitting element OLED may emit light having a predetermined luminance according to the driving current.

In FIG. 4, the case where the pixel circuit PC includes two thin film transistors and one storage capacitor is described, but the disclosure is not limited thereto. In another embodiment, the pixel circuit PC may include seven thin film transistors and one storage capacitor, for example. In another embodiment, the pixel circuit PC may include two or more storage capacitors.

FIG. 5 is a schematic cross-sectional view illustrating an embodiment of a cross-section taken along line I-I' in FIG. 2.

Referring to FIG. 5, a display module DM of an embodiment may include an electronic panel EP. The electronic panel EP may include a display panel DP and an input sensor ISP on the display panel DP. The display panel DP may include the substrate SUB, a circuit layer CEL on the substrate SUB, a light-emitting element layer LEL on the circuit layer CEL, and a thin film encapsulation layer TFE on the light-emitting element layer LEL.

The substrate SUB may provide a base surface on which the circuit layer CEL is disposed. The substrate SUB may include a flexible substrate capable of bending, folding, rolling, etc. The substrate SUB may include a glass substrate, a metal substrate, or a polymer substrate. However, the embodiment of the disclosure is not limited thereto, and the substrate SUB may include an inorganic layer, an organic layer, or a composite material layer.

The circuit layer CEL may be disposed on the substrate SUB. The circuit layer CEL may include insulating layers, transistors each including a semiconductor pattern, circuit wires connected to the transistors, and conductive patterns.

The light-emitting element layer LEL may be disposed on the circuit layer CEL. The light-emitting element layer LEL may include a light-emitting element. In an embodiment, the light-emitting element may include an organic light-emitting material, an inorganic light-emitting material, an organic-inorganic light-emitting material, a quantum dot, a quantum rod, a micro light-emitting diode (“LED”), or a nano LED, for example.

The thin film encapsulation layer TFE may be disposed on the light-emitting element layer LEL. The thin film encapsulation layer TFE may protect the light-emitting element layer LEL from foreign substances, such as moisture, oxygen, and dust particles. The thin film encapsulation layer TFE may include at least one inorganic layer. The thin film encapsulation layer TFE may include a stack structure of an inorganic layer/an organic layer/an inorganic layer.

The input sensor ISP may include a plurality of electrodes (not shown) detecting external input, trace lines (not shown) connected to the electrodes, and an organic layer and/or inorganic layer, which insulates and/or protects the electrodes or the trace lines. The input sensor ISP may include a capacitive sensor but is not particularly limited thereto.

The input sensor ISP may be disposed directly on the display panel DP. The display panel DP and the input sensor ISP may be formed through sequential processes. Therefore, a separate adhesive layer may not be disposed between the input sensor ISP and the display panel DP.

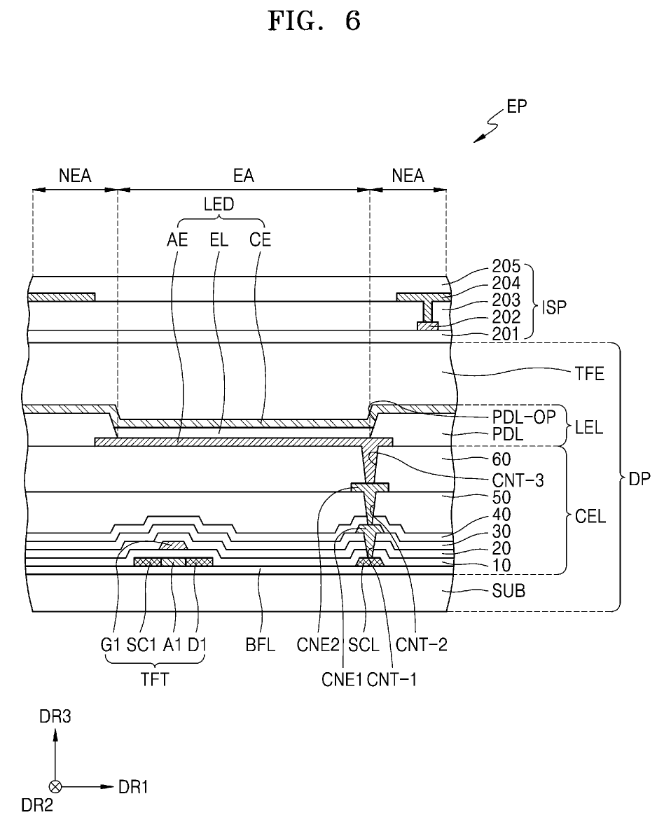

FIG. 6 is a schematic cross-sectional view illustrating an embodiment of an electronic panel EP according to the disclosure. Although only one light-emitting region EA is shown in the drawing, this is merely one of embodiments, and multiple light-emitting regions EA may be provided.

Referring to FIG. 6, in an embodiment of according to the disclosure, the electronic panel EP may include a display panel DP and an input sensor ISP.

Here, the display panel DP may include a substrate SUB, a circuit layer CEL, a light-emitting element layer LEL, and a thin film encapsulation layer TFE.

The substrate SUB may have a multi-layer structure. In an embodiment, the substrate SUB may have a three-layer structure of a synthetic resin layer, an adhesive layer, and a synthetic resin layer, for example. In particular, the synthetic resin layer may include polyimide-based resin. The synthetic resin layer may include at least one selected from the group consisting of acrylate resin, methacrylate resin, polyisoprene resin, vinyl resin, epoxy resin, urethane resin, cellulose resin, siloxane resin, polyamide resin, and perylene resin.

The circuit layer CEL may be placed on the substrate SUB. The circuit layer CEL may include an insulating layer, a semiconductor pattern, a conductive pattern, a signal line, and a driving circuit of a pixel. In an embodiment, the circuit layer CEL may include a buffer layer BFL, first to fifth insulating layers 10, 20, 30, 40, and 50, a signal transfer region SCL, and a plurality of connection electrodes (e.g., CNE1 and CNE2), for example.

The buffer layer BFL may be disposed on a substrate SUB. The buffer layer BFL may prevent metal atoms or impurities from diffusing from the substrate SUB to an upper semiconductor pattern. The semiconductor pattern may include an active region A1 of a transistor TFT. A rear metal layer may be additionally disposed between the substrate SUB and the buffer layer BFL. The rear metal layer may be disposed below the transistor TFT and may block external light from reaching the transistor TFT.

The semiconductor pattern may be disposed on the buffer layer BFL. The semiconductor pattern may include a silicon semiconductor. In an embodiment, the silicon semiconductor may include amorphous silicon, polycrystalline silicon, or the like, for example. In an embodiment, the semiconductor pattern may include low-temperature polysilicon, for example.

The transistor TFT may include a source region SC1 (or a source), the active region A1 (or a channel), a drain region D1 (or a drain), and a gate G1. The source region SC1, the active region A1, and the drain region D1 of the transistor TFT may be formed from the semiconductor pattern. The source region SC1 and the drain region D1 may extend in opposite directions from the active region A1 in a cross-section. FIG. 4 illustrates a portion of the signal transfer region SCL formed from the semiconductor pattern. Although not shown separately, the signal transfer region SCL may be connected to the drain region D1 of the transistor TFT in a plan view.

The first insulating layer 10 may be disposed on the buffer layer BFL. The first insulating layer 10 may cover the source region SC1, the active region A1, the drain region D1, and the signal transfer region SCL of the transistor TFT arranged on the buffer layer BFL.

The first insulating layer 10 may include an inorganic layer and/or an organic layer and may have a single-layer or multi-layer structure. The inorganic layer may include at least one selected from the group consisting of aluminum oxide, titanium oxide, silicon oxide, silicon nitride, silicon oxynitride, zirconium oxide, and hafnium oxide. In an embodiment, the first insulating layer 10 may include a single-layer silicon oxide layer. As well as the first insulating layer 10, an insulating layer of the circuit layer CEL described below may include an inorganic layer and/or an organic layer and may have a single-layer or multi-layer structure. The inorganic layer may include at least one of the materials described above but is not limited thereto.

The gate G1 of the transistor TFT may be disposed on the first insulating layer 10. The gate G1 may be a part of a metal pattern. The gate G1 may overlap the active region A1. In a process of doping the semiconductor pattern, the gate G1 may function as a mask. The gate G1 may include, but not particularly limited to, titanium (Ti), silver (Ag), an alloy including or consisting of silver, molybdenum (Mo), an alloy including or consisting of molybdenum, aluminum (Al), an alloy including or consisting of aluminum, aluminum nitride (AlN), tungsten (W), tungsten nitride (WN), copper (Cu), indium tin oxide (“ITO”), indium zinc oxide (“IZO”), or the like.

The second insulating layer 20 may be disposed on the first insulating layer 10 and may cover the gate G1. The third insulating layer 30 may be disposed on the second insulating layer 20.

A first connection electrode CNE1 may be disposed on the third insulating layer 30. The first connection electrode CNE1 may be connected to the signal transfer region SCL through a contact hole CNT-1 which penetrates the first to third insulating layers 10, 20, and 30. The fourth insulating layer 40 may be disposed on the third insulating layer 30 to cover the first connection electrode CNE1. The fourth insulating layer 40 may include an organic layer.

The fifth insulating layer 50 may be disposed on the fourth insulating layer 40. A second connection electrode CNE2 may be disposed on the fifth insulating layer 50. The second connection electrode CNE2 may be connected to the first connection electrode CNE1 through a contact hole CNT-2, which penetrates the fourth insulating layer 40 and the fifth insulating layer 50. The fifth insulating layer 50 may include an organic layer.

A sixth insulating layer 60 may be disposed on the fifth insulating layer 50 to cover the second connection electrode CNE2. The sixth insulating layer 60 may include an organic layer. The stack structure of the first to sixth insulating layers 10, 20, 30, 40, 50, and 60 is only an illustrative embodiment. Additional conductive layer and insulating layer may be further provided in addition to the first to sixth insulating layers 10, 20, 30, 40, 50, and 60.

The light-emitting element layer LEL may be disposed on the circuit layer CEL. The light-emitting element layer LEL may include a light-emitting element LED and a pixel defining layer PDL. In an embodiment, the light-emitting element layer LEL may include an organic light-emitting material, a quantum dot, a quantum rod, a micro LED, or a nano LED, for example.

The light-emitting element LED may include a first electrode AE, a light-emitting layer EL, and a second electrode CE.

The first electrode AE may be disposed on the sixth insulating layer 60. The first electrode AE may be connected to the second connection electrode CNE2 through a contact hole CNT-3 penetrating the sixth insulating layer 60.

The pixel defining layer PDL may be disposed on the sixth insulating layer 60 and may cover a portion of the first electrode AE. An opening PDL-OP may be defined in the pixel defining layer PDL. The opening PDL-OP in the pixel defining layer PDL may expose at least a portion of the first electrode AE. In an embodiment, the light-emitting region EA may be defined in correspondence to a portion of the first electrode AE exposed by the opening PDL-OP. A non-light-emitting region NEA may surround the light-emitting region EA.

The light-emitting layer EL may be disposed on the first electrode AE. The light-emitting layer EL may be disposed in the opening PDL-OP. That is, the light-emitting layer EL may be separately formed for each pixel. When the light-emitting layer EL is separately formed for each pixel, the light-emitting layer EL may emit light of at least one color selected from among blue, red, and green. However, the disclosure is not limited thereto, and the light-emitting layer EL may be connected to pixels and provided in common. In this case, the light-emitting layer EL may provide blue light or white light.

The second electrode CE may be disposed on the light-emitting layer EL. The second electrode CE may be disposed, as an integral body, in common for a plurality of pixels. A common voltage may be provided to the second electrode CE, and the second electrode CE may be also referred to as a common electrode.

The light-emitting layer EL may include an organic light-emitting layer including or consisting of an organic material. The light-emitting layer EL may include a hole transporting layer, an organic light-emitting layer, and an electron transporting layer. When the first electrode AE receives a predetermined voltage through a thin film transistor of the circuit layer CEL and the second electrode CE receives a common voltage, holes and electrons may move to the organic light-emitting layer through the hole transporting layer and the electron transporting layer, respectively, and may be combined with each other in the organic light-emitting layer so as to emit light. In an embodiment, the first electrode AE may correspond to an anode electrode, and the second electrode CE may correspond to a cathode electrode, for example, but the disclosure is not limited thereto.

In an embodiment, a plurality of light-emitting elements LED may include a quantum dot light-emitting diode including a quantum dot light-emitting layer, an inorganic light-emitting diode including an inorganic semiconductor, or a micro-light-emitting diode, for example.

The thin film encapsulation layer TFE may be disposed on the second electrode CE. Although not shown, the thin film encapsulation layer TFE may have a multi-layer structure in which at least one organic encapsulation layer and at least one inorganic encapsulation layer are alternately stacked. The thin film encapsulation layer TFE may protect a display unit from external moisture.

The organic encapsulation layer may provide a flat base surface so that even when the input sensor ISP described below is formed through a continuous process, a defect rate may be reduced.

The input sensor ISP may include a base insulating layer 201, a first conductive layer 202, a sensing insulating layer 203, a second conductive layer 204, and a cover insulating layer 205.

The base insulating layer 201 may include an inorganic layer including silicon nitride, silicon oxynitride, or silicon oxide. In an alternative embodiment, the base insulating layer 201 may include an organic layer including epoxy resin, acrylic resin, or imide-based resin. The base insulating layer 201 may have a single-layer structure or a multi-layer structure in which multiple layers are stacked in the third direction DR3.

Each of the first conductive layer 202 and the second conductive layer 204 may have a single-layer structure or a multi-layer structure in which multiple layers are stacked in the third direction DR3.

A conductive layer having a single-layer structure may include a metal layer or a transparent conductive layer. The metal layer may include molybdenum, silver, titanium, copper, aluminum, or any alloys thereof. The transparent conductive layer may include transparent conductive oxide, such as indium tin oxide (“ITO”), indium zinc oxide (“IZO”), zinc oxide (ZnO), or indium zinc tin oxide (“IZTO”).

A conductive layer having a multi-layer structure may include metal layers. In an embodiment, the metal layers may have a three-layer structure of titanium/aluminum/titanium. The conductive layer having a multi-layer structure may include at least one metal layer and at least one transparent conductive layer, for example.

At least one of the sensing insulating layer 203 and the cover insulating layer 205 may include an inorganic film. The inorganic film may include at least one selected from the group consisting of aluminum oxide, titanium oxide, silicon oxide, silicon oxynitride, zirconium oxide, and hafnium oxide.

At least one of the sensing insulating layer 203 and the cover insulating layer 205 may include an organic film. The organic film may include at least one selected from the group consisting of acrylic resin, methacrylic resin, polyisoprene, vinyl resin, epoxy resin, urethane resin, cellulose resin, siloxane resin, polyimide resin, polyamide resin, and perylene resin.

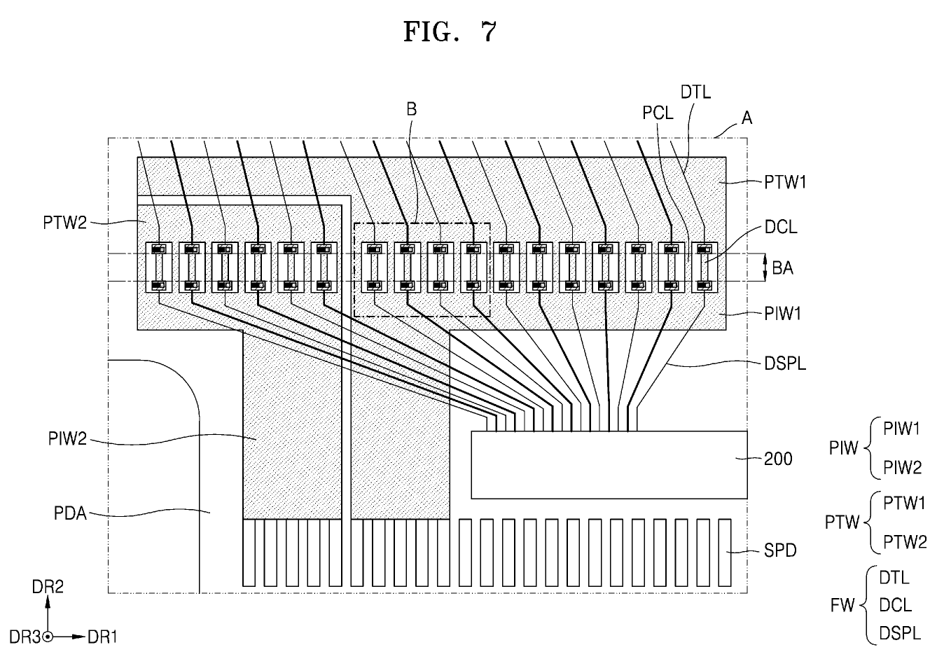

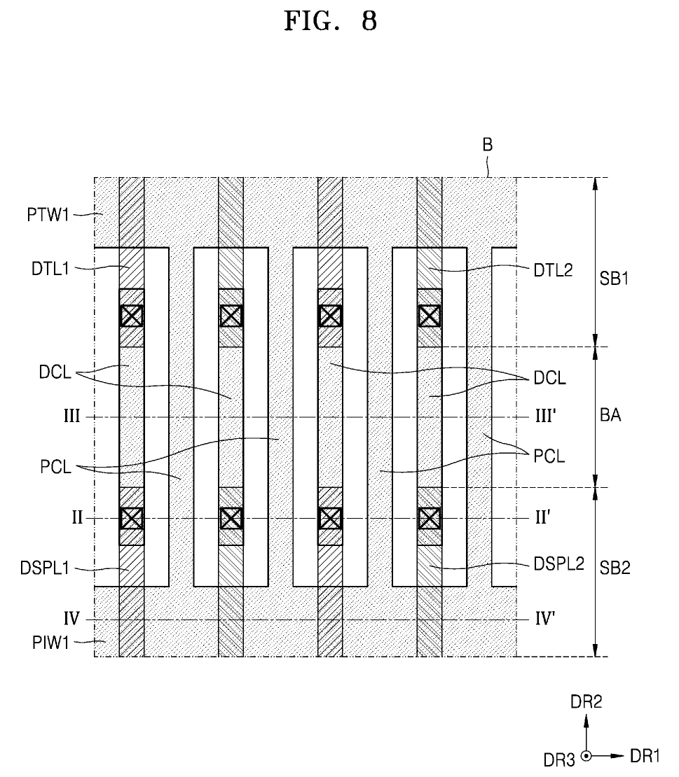

FIG. 7 is an enlarged conceptual diagram of a region A in FIG. 2. FIG. 8 is an enlarged conceptual diagram of a region B in FIG. 7.

Referring to FIG. 7, a plurality of fan-out wires FW, a first power wire, a second power wire, etc., may be arranged in a non-display area NDA of the display device DD.

Specifically, the display driving circuit 200 and the signal pads SPD, which have been described above, may be arranged in the pad area PDA, and a plurality of wires may be arranged across the bending region BA from the pad area PDA.

In an embodiment, the fan-out wires FW may be connected to the display driving circuit 200 and may extend from the display driving circuit 200 across the bending region BA to the display area DA. To put this in another perspective, the fan-out wires FW may extend from the pad area PDA to the display area DA across the bending region BA.

Here, the fan-out wires FW may correspond to a plurality of data lines DL. The fan-out wire FW may be electrically connected to the data lines DL, respectively.

Although not shown, the fan-out wires FW may be connected to the display driving circuit 200 via a pad. In this way, the fan-out wires FW may connect the display driving circuit 200 to the pixel circuit PC (in FIG. 4).

Each of the fan-out wires FW may include a data supply wire DSPL, a data transfer wire DTL, and a data connection wire DCL.

The data supply wire DSPL may be disposed in the second region 2A. The data supply wire DSPL may be connected to output terminals of the display driving circuit 200. Specifically, an end of the data supply wire DSPL may be connected to output terminals of the display driving circuit 200, and an opposite end of the data supply wire DSPL may be electrically connected to the data connection wire DCL in a bending periphery next (adjacent) to the bending region BA.

The data transfer wire DTL may be disposed in the first region 1A. The data transfer wire DTL may be connected to a data line DL of the display area DA. Specifically, an end of the data transfer wire DTL may be electrically connected to the data connection wire DCL in the bending periphery next (adjacent) to the bending region BA.

That is, the data connection wire DCL may electrically connect the data supply wire DSPL to the data transfer wire DTL.

According to the related art, the fan-out wires FW crossing the bending region BA are discontinuously arranged in clusters. That is, several fan-out wires FW are arranged within a predetermined width to form a block, and each block is disposed to be spaced apart from another block. That is, not the fan-out wires FW but power wires are arranged between blocks. Therefore, according to the related art, there is a problem in that a difference in luminance occurs due to a difference in resistance of the fan-out wires FW between blocks.

The disclosure is characterized by having a structure in which a block of fan-out wires FW is removed to solve this problem.

In an embodiment of the disclosure, the fan-out wires FW may be continuously arranged in a width direction parallel with a bending axis direction. A power connection wire PCL may be disposed between two fan-out wires FW next (adjacent) to each other. This is described in detail below.

The display device DD may include power wire disposed on the substrate SUB. The power wire may include a first power wire and a second power wire that respectively transmit first power and second power to drive light-emitting elements LED of the light-emitting element layer LEL. Here, the first power wire may apply the driving voltage ELVDD, and the second power wire may apply the common voltage ELVSS.

The first power wire may include a first power input wiring PIW1, a first power transfer wiring PTW1, and a power connection wire PCL connecting the first power input wiring PIW1 to the first power transfer wiring PTW1. Similarly, the second power wire may include a second power input wiring PIW2, a second power transfer wiring PTW2, and a power connection wire PCL connecting the second power input wiring PIW2 to the second power transfer wiring PTW2.

The first power input wiring PIW1 may include a portion extending from the pad area PDA toward the bending region BA in the second direction DR2 and a bending periphery disposed along the first direction DR1 corresponding to the bending axis. That is, at least a portion of the first power input wiring PIW1 may be disposed in a second sub-region SB2.

The first power transfer wiring PTW1 may include a bending periphery disposed along the first direction DR1 corresponding to the bending axis of the substrate SUB. That is, at least a portion of the first power transfer wiring PTW1 may be disposed in a first sub-region SB1.

An end of each of a plurality of power connection wires PCL may be connected to the bending periphery of the first power transfer wiring PTW1, and an opposite end of each power connection wire PCL may be connected to the bending periphery of the first power input wiring PIW1.

The second power input wiring PIW2 may include a portion extending from the pad area PDA toward the bending region BA in the second direction DR2 and a bending periphery disposed along the first direction DR1 corresponding to the bending axis. That is, at least a portion of the second power input wiring PIW2 may be disposed in the second sub-region SB2.

The second power transfer wiring PTW2 may include a bending periphery disposed along the first direction DR1 corresponding to the bending axis of the substrate SUB. That is, at least a portion of the second power transfer wiring PTW2 may be disposed in the first sub-region SB1.

Referring to FIG. 8, an end of each of the plurality of power connection wires PCL may be connected to the bending periphery of the first power transfer wiring PTW1, and an opposite end of each of the power connection wires PCL may be connected to the bending periphery of the first power input wiring PIW1.

To put this in another perspective, each of the power connection lines PCL may be arranged from the second sub-region SB2 toward the first sub-region SB1 across the bending region BA.

That is, the power connection wires PCL may be arranged across the bending region BA and may transmit power for driving the light-emitting elements LED of a plurality of pixels PX.

The fan-out wires FW and the power connection wires PCL may be arranged alternately in the bending region BA.

Specifically, the data connection wire DCL may connect the data supply wire DSPL to the data transfer wire DTL, and the data connection wires DCL and the power connection wires PCL may be alternately arranged in the bending region BA.

An end portion of the data supply wire DSPL may extend in the second sub-region SB2 toward the bending region BA. Here, the end portion of the data supply wire DSPL may be disposed between the power connection lines PCL in a plan view.

An end portion of the data transfer wire DTL may extend in the first sub-region SB1 toward the bending region BA. Here, the end portion of the data transfer wire DTL may be disposed between the power connection lines PCL in a plan view.

In other words, the data supply wire DSPL extending from the display driving circuit 200 may be disposed between the power connection wires PCL in the second sub-region SB2 and may be electrically connected to the data connection wire DCL, and the data transfer wire DTL electrically connected to the data connection wire DCL may be disposed between the power connection wires PCL in the first sub-region SB1 and may extend toward the display area DA.

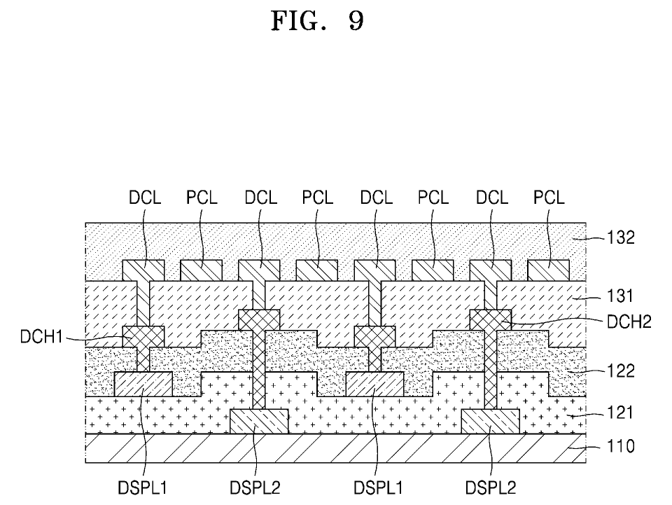

FIG. 9 is a schematic cross-sectional view illustrating an embodiment of a cross-section taken along line II-II' in FIG. 8. The substrate SUB is omitted from FIG. 9, and a buffer layer may be disposed on the substrate (not shown).

Referring to FIG. 9, the first layer may correspond to a buffer layer. The buffer layer may be intended to prevent the penetration of oxygen or moisture through the substrate SUB.

The buffer layer may include at least one inorganic film. In an embodiment, the buffer layer may have a multi-layer structure in which one or more inorganic films are alternately stacked, wherein the inorganic films may include one or more of a silicon nitride film, a silicon oxynitride film, a silicon oxide film, a titanium oxide film, and an aluminum oxide film, for example.

In another embodiment, the first layer may correspond to a first insulating layer 110 on the buffer layer. The first insulating layer 110 may include an inorganic layer and/or an organic layer and may have a single-layer or multi-layer structure.

The inorganic layer may include at least one selected from the group consisting of aluminum oxide, titanium oxide, silicon oxide, silicon nitride, silicon oxynitride, zirconium oxide, and hafnium oxide.

Data supply wires DSPL may be arranged across the pad area PDA and the second sub-region SB2. Two data supply wires DSPL next (adjacent) to each other may be in different layers from each other. Here, for convenience, a data supply wire DSPL disposed in a relatively upper layer is also referred to as a first data supply wire DSPL1, and a data supply wire DSPL disposed in a relatively lower layer is also referred to as a second data supply wire DSPL2.

In an embodiment, the second data supply wire DSPL2 may be disposed on the first insulating layer 110.

A second insulating layer 121 may be disposed on the first insulating layer 110 and may cover the second data supply wire DSPL2. The second insulating layer 121 may include an inorganic layer and/or an organic layer and may have a single-layer or multi-layer structure.

The first data supply wire DSPL1 may be disposed on the second insulating layer 121. A third insulating layer 122 may be disposed on the second insulating layer 121 and may cover the first data supply wire DSPL1. The third insulating layer 122 may include an inorganic layer and/or an organic layer and may have a single-layer or multi-layer structure.

A fourth insulating layer 131 may be disposed on the third insulating layer 122. The fourth insulating layer 131 may function as a first flattening layer. The fourth insulating layer 131 may include an organic film, such as an acrylic resin film, an epoxy resin film, a phenolic resin film, a polyamide resin film, or a polyimide resin film.

Data connection wires DCL and power connection wires PCL may be arranged on the fourth insulating layer 131. A fifth insulating layer 132 may be disposed on the fourth insulating layer 131 and may cover the data connection wires DCL and the power connection wires PCL. Like the fourth insulating layer 131, the fifth insulating layer 132 may also include an organic film and may function as a second flattening layer.

In other words, the power connection wires PCL and the data connection wires DCL may be arranged on the first flattening layer, and the second flattening layer may be disposed on the power connection wires PCL and the data connection wires DCL.

In the second sub-region SB2, a data supply wire DSPL may be disposed in a different layer than a data connection wire DCL. Specifically, the data connection wire DCL may be disposed in an upper layer than the data supply wire DSPL. In an embodiment, the data connection wire DCL may be disposed on the fourth insulating layer 131 to be in the same layer as the power connection wires PCL, and the data supply wire DSPL may be disposed on the first or second insulating layer 110 or 121, for example.

A conductive layer forming the first data supply wire DSPL1 may be electrically connected to the data connection wire DCL through a contact hole defined in insulating layers above the conductive layer in the second sub-region SB2. In an embodiment, the first data supply wire DSPL1 may be electrically connected to the data connection wire DCL through a contact hole defined in the third insulating layer 122 and a connection electrode DCH1 disposed on the third insulating layer 122, for example.

To this end, when viewed in the third direction DR3 perpendicular to the substrate SUB, a leading end of the first data supply wire DSPL1 may be disposed to overlap an end portion of the data connection wire DCL.

A conductive layer forming the second data supply wire DSPL2 may be electrically connected to the data connection wire DCL through a contact hole defined in insulating layers on the conductive layer in the second sub-region SB2. In an embodiment, the second data supply wire DSPL2 may be electrically connected to the data connection wire DCL through a contact hole defined in the second insulating layer 121 and a connection electrode DCH2 disposed on the second insulating layer 121, for example.

To this end, when viewed in the third direction DR3 perpendicular to the substrate SUB, a leading end of the second data supply wire DSPL2 may be disposed to overlap one end portion of the data connection wire DCL.

Similarly, the data transfer wire DTL disposed in the first sub-region SB1 may be disposed in a different layer than the data connection wire DCL. Specifically, the data connection wire DCL may be disposed in an upper layer than the data transfer wire DTL. In an embodiment, the data connection wire DCL may be disposed on the fourth insulating layer 131 to be in the same layer as the power connection wires PCL, and the data transfer wire DTL may be arranged on the first or second insulating layer 110 or 121, for example.

In this way, the data supply wire DSPL and the data transfer wire DTL may be arranged in the same layer.

In an embodiment, the fan-out wires FW may transmit a first data signal and a second data signal, which are different from each other. In an embodiment, among the data supply wires DSPL, the first data supply wire DSPL1 may transmit the first data signal, and the second data supply wire DSPL2 may transmit the second data signal, for example.

Among a plurality of data transfer wires DTL, a first data transfer wire DTL1 may transmit the first data signal, and a second data transfer wire DTL2 may transmit the second data signal.

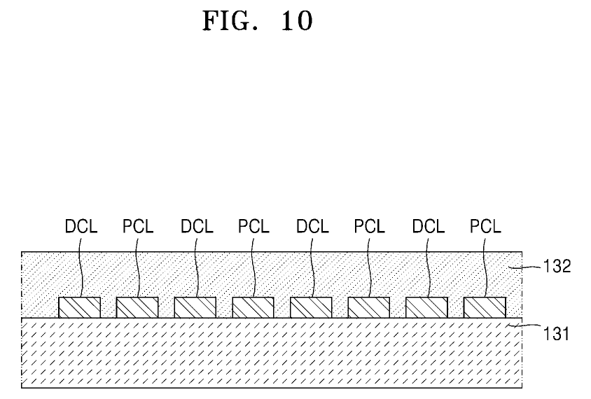

FIG. 10 is a schematic cross-sectional view illustrating an embodiment of a cross-section taken along line III-III' in FIG. 8. The substrate SUB is omitted from FIG. 10.

Referring to FIG. 10, the first data supply wire DSPL1, the second data supply wire DSPL2, the first data transfer wire DTL1, and the second data transfer wire DTL2 may not be arranged in the bending region BA. Only the power connection wire PCL and the data connection wire DCL may be arranged in the bending region BA. At this time, the power connection wire PCL and the data connection wire DCL may be arranged between the fourth insulating layer 131 and the fifth insulating layer 132, which are organic layers. That is, the first to third insulating layers 110, 121, and 122, which are lower inorganic film layers, may be omitted from the bending region BA.

In other words, in the bending region BA, the fan-out wire FW may transmit data signals through the data connection wire DCL that is disposed in the same layer as the power connection wire PCL.

As described above, a plurality of data connection wires DCL and a plurality of power connection wires PCL may be alternately arranged in the bending region BA. To put this in another perspective, in the bending region BA, the power connection wire PCL may be disposed between data connection wires DCL next (adjacent) to each other. To put this in another perspective, in the bending region BA, the data connection wire DCL may be disposed between power connection wires PCL next (adjacent) to each other.

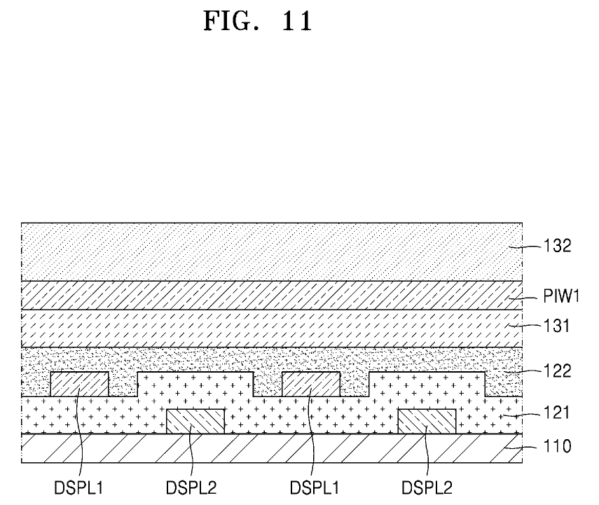

FIG. 11 is a schematic cross-sectional view illustrating an embodiment of a cross-section taken along line IV-IV' in FIG. 8. The substrate SUB is omitted from FIG. 11.

Referring to FIG. 11, in the pad area PDA and the second sub-region SB2 next (adjacent) to the pad area PDA, the second data supply wire DSPL2 may be disposed on the first insulating layer 110, and the second insulating layer 121 may be disposed on the first insulating layer 110 and may cover the second data supply wire DSPL2.

The first data supply wire DSPL1 may be disposed on the second insulating layer 121, and the third insulating layer 122 may be disposed on the second insulating layer 121 and cover the first data supply wire DSPL1.

The fourth insulating layer 131 may be disposed on the third insulating layer 122, and the first power input wiring PIW1 may be disposed on the fourth insulating layer 131. The fifth insulating layer 132 may be disposed on the fourth insulating layer 131 and may cover the first power input wiring PIW1. In other words, the first power input wiring PIW1 may be disposed between the fourth insulating layer 131 and the fifth insulating layer 132. In this way, the first power input wiring PIW1 may be disposed on the data supply wire DSPL.

To put this in another perspective, in the pad area PDA, the data supply wire DSPL may be disposed below a power input wiring PIW, and the fan-out wire FW may not be disposed in the layer in which the power input wiring PIW is disposed.

In the non-display area NDA and the first sub-region SB1 next (adjacent) to the non-display area NDA, the second data transfer wire DTL2 may be disposed on the first insulating layer 110, and the second insulating layer 121 may be disposed on the first insulating layer 110 and may cover the second data transfer wire DTL2.

The first data transfer wire DTL1 may be disposed on the second insulating layer 121, and the third insulating layer 122 may be disposed on the second insulating layer 121 and may cover the first data transfer wire DTL1.

The fourth insulating layer 131 may be disposed on the third insulating layer 122, and the first power transfer wiring PTW1 may be disposed on the fourth insulating layer 131. The fifth insulating layer 132 may be disposed on the fourth insulating layer 131 and may cover the first power transfer wiring PTW1. In other words, the first power transfer wiring PTW1 may be disposed between the fourth insulating layer 131 and the fifth insulating layer 132. In this way, the first power transfer wiring PTW1 may be disposed on the data transfer wire DTL.

To put this in another perspective, in the non-display area NDA and the first sub-region SB1 next (adjacent) to the non-display area NDA, the data transfer wire DTL may be disposed below a power transfer wiring PTW, and the fan-out wire FW may not be disposed in the layer in which the power transfer wiring PTW is disposed.

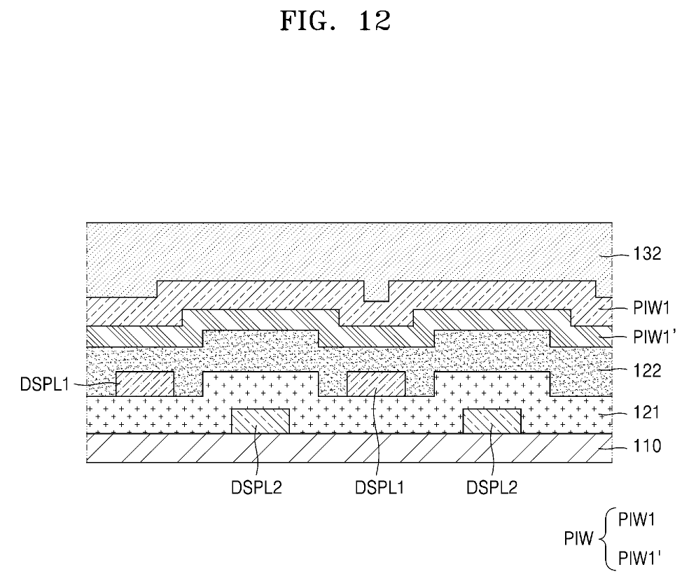

FIG. 12 is a schematic cross-sectional view illustrating another embodiment of the cross-section taken along line IV-IV' in FIG. 8. The substrate SUB is omitted from FIG. 12.

Referring to FIG. 12, the arrangement of first data supply wire DSPL1, the second data supply wire DSPL2, and the first to third insulating layers 110, 121, and 122 may be the same as or similar to that in the display device DD according to FIG. 11.

However, the display device DD according to FIG. 12 may include a power input wiring PIW having a multi-layer structure. In an embodiment, a first-2 power input wiring PIW1' may be disposed on the third insulating layer 122, and the first power input wiring PIW1 may be disposed on the first-2 power input wiring PIW1', for example. The fifth insulating layer 132 may be disposed on the first power input wiring PIW1 to cover the first power input wiring PIW1. In other words, the power input wiring PIW may be disposed between the third insulating layer 122 and the fifth insulating layer 132. That is, even when the power input wiring PIW has a multi-layer structure (e.g., double-layer structure), the power input wiring PIW may be disposed on the data supply wire DSPL.

The arrangement relationship between the first power wire and the fan-out wire FW has been explained using the region B in FIG. 7 as an example.

The arrangement relationship between the second power wire and the fan-out wire FW illustrated in FIG. 7 is substantially the same as the arrangement relationship between the first power wire and the fan-out wire FW, and thus, detailed descriptions thereof are omitted.

A display device in embodiments may be applied to various electronic devices. In an embodiment, an electronic device may include the display device described above and may further include a module or device having additional functions in addition to the display device.

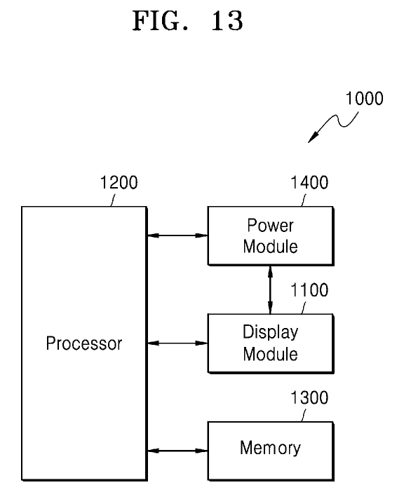

FIG. 13 is a block diagram of an embodiment of an electronic device. Referring to FIG. 13, an electronic device 1000 may include a display module 1100, a processor 1200, a memory 1300, and a power module 1400.

The processor 1200 may include at least one selected from the group consisting of a central processing unit (“CPU”), an application processor (“AP”), a graphics processing unit (“GPU”), a communication processor (“CP”), an image signal processor (“ISP”), and a controller. In an embodiment, the processor 1200 may be divided into two or more parts in a functional or structural perspective. In an embodiment, the processor 1200 may include a main processor as a first driver chip including a CPU and an auxiliary processor as a second driver chip including a controller that receives an image signal from the main processor and processes the image signal to meet the interface specifications of the display module 1100, for example.

The memory 1300 may include at least one of non-volatile memory and volatile memory. Data information desired for the operation of the processor 1200 or the display module 1100 may be stored in the memory 1300. When the processor 1200 executes an application stored in the memory 1300, an image data signal and/or an input control signal may be transmitted to the display module 1100, and the display module 1100 may process the received signal and output image information through a display screen.

The power module 1400 may include a power supply module, such as a power adapter or a battery device, and a power conversion module that converts power supplied by the power supply module to generate power desired for the operation of the electronic device 1000. Power conversion by the power conversion module may include, but is not limited to, direct current to direct current (“DC-DC”) conversion, alternating current to direct current (“AC-DC”) conversion, and direct current to direct current (“DC-AC”) conversion.

At least one of the components of the electronic device 1000 may be included in a display device in the embodiments described above. Some of the individual modules functionally included in a single module may be included in the display device, and remaining (the other) individual modules may be provided separately from the display device. In an embodiment, the display device may include the display module 1100 and the auxiliary processor of the processor 1200, for example. The main processor of the processor 1200, the memory 1300, and the power module 1400 may be provided in other forms than the form of the display device in the electronic device 1000. In an embodiment, the power module 1400 may be provided in the display device and may supply power to the processor 1200 and the memory 1300, which are provided in the electronic device 1000 other than the display device, for example. The disclosure is not limited to the above embodiments.

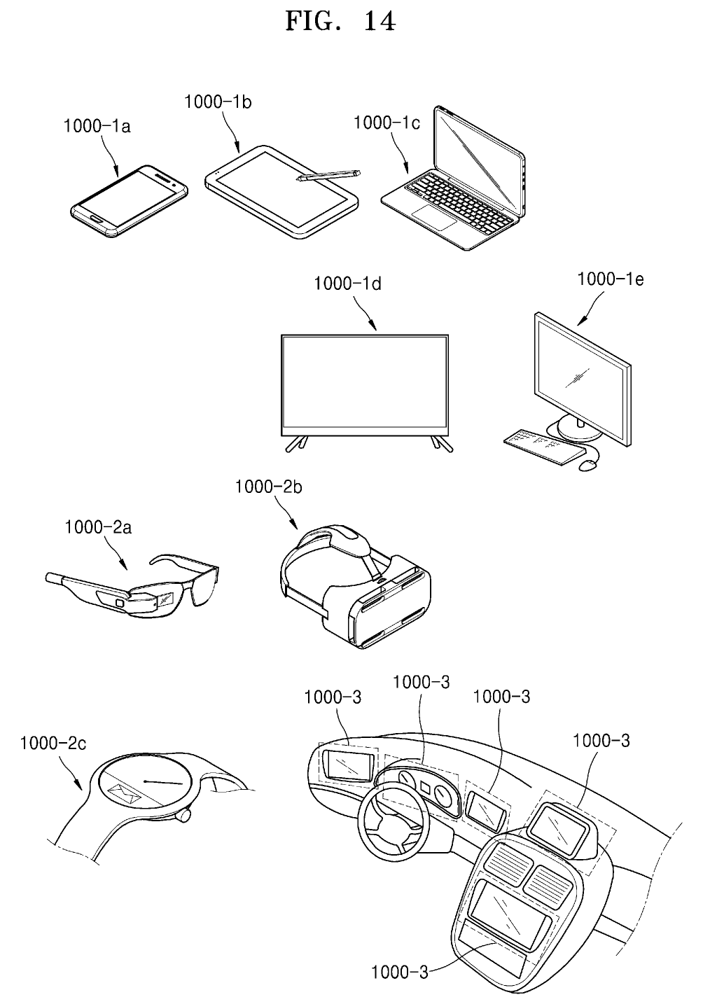

FIG. 14 is a schematic diagram of embodiments of electronic devices.

Referring to FIG. 14, various electronic devices to which a display device in embodiments is applied may include image display electronic devices, such as a smart phone 1000-1a, a tablet personal computer 1000-1b, a laptop computer 1000-1c, a television (“TV”) 1000-1d, and a desk monitor 1000-1e, wearable electronic devices, such as smart glasses 1000-2a, an HMD 1000-2b, and a smart watch 1000-2c, each including a display module, and vehicle electronic devices 1000-3, such as a car instrument panel, center fascia, a CID disposed on a dashboard, and a room mirror display, each including a display module.

The electronic devices in FIG. 14 may include the components illustrated in FIG. 13. In an embodiment, the smart phone 1000-1a may include the display module 1100, the processor 1200, the memory 1300, and the power module 1400 in FIG. 13, for example. The smart phone 1000-1a may further include a communication module and a battery device. Power provided from the battery device may be converted by the power module 1400 and then provided to the processor 1200, the memory 1300, and the display module 1100. In an embodiment, a display device applied to the smart phone 1000-1a may include the display module 1100 and may further include the power module 1400. The processor 1200 and the memory 1300 may be provided as chips disposed (e.g., mounted) on a motherboard, which is an external device, but are not limited thereto.

By an embodiment of the disclosure, a display device having improved luminance deviation and an electronic device including the same may be provided.

However, these effects are illustrative, and the effects of the disclosure are not limited thereto.

Each of the embodiments described above may be implemented independently, but it should be noted that the structure of each embodiment may be applied in combination to other embodiments.

Although the disclosure has been described with reference to the embodiments shown in the drawings, these are merely exemplary, and those skilled in the art will understand that various modifications may be made in the embodiments and equivalent other embodiments may be inferred therefrom. Therefore, the technical scope of the disclosure should be defined by the spirit of the appended claims.

The particular implementations described herein are illustrative embodiments of embodiments and are not intended to otherwise limit the scope of the embodiments in any way. Moreover, no component is essential to the practice of embodiments unless the component is specifically described as "essential" or "critical."

The use of the terms "a", and "an" and "the" and similar referents in the context describing embodiments (especially in the context of the following claims) are to be construed to cover both the singular and the plural. Furthermore, recitation of ranges of values herein are merely intended to serve as a shorthand method of referring individual to each separate value falling within the range, unless otherwise indicated herein, and each separate value is incorporated into the specification as when it were individually recited herein. Also, the steps of all methods described herein may be performed in any suitable order unless otherwise indicated herein or otherwise clearly contradicted by context. The disclosure is not limited to the described order of the steps. The use of any and all examples or exemplary language provided herein is intended merely to elaborate embodiments and does not pose a limitation on the scope of embodiments unless otherwise claimed. Numerous modifications and adaptations will be readily apparent to one of ordinary skill in the art without departing from the spirit and scope of the appended claims or their equivalents.

What is claimed is:

1. A display device comprising:
a substrate including:
a first region including:
a display area in which a plurality of pixels are arranged; and
a non-display area surrounding the display area;
a second region spaced from the first region and including a pad area; and
a bending region between the first region and the second region;
a plurality of data lines arranged in the display area and configured to transmit a data signal to the plurality of pixels;
a plurality of fan-out wires extending from the pad area to the display area across the bending region and respectively corresponding to the plurality of data lines; and
a plurality of power connection wires arranged across the bending region and configured to transmit power to light-emitting elements of the plurality of pixels,
wherein the plurality of fan-out wires and the plurality of power connection wires are alternately arranged in the bending region.

2. The display device of claim 1, wherein
the plurality of fan-out wires are electrically connected to the plurality of data lines, respectively.

3. The display device of claim 1, wherein
each of the plurality of fan-out wires includes:
a data supply wire connected to output terminals of a display driving circuit;
a data transfer wire connected to one of the plurality of data lines of the display area; and
a data connection wire electrically connecting the data supply wire to the data transfer wire.

4. The display device of claim 3, wherein
the data supply wire is disposed in the second region, and the data transfer wire is disposed in the first region.

5. The display device of claim 3, wherein
a plurality of data connection wires respectively included in the plurality of fan-out wires are arranged alternately with the plurality of power connection wires.

6. The display device of claim 3, wherein
the data supply wire is disposed in a different layer than the data connection wire and at least partially overlaps the data connection wire.

7. The display device of claim 6, wherein
the data supply wire is
electrically connected to the data connection wire through a contact hole defined in an insulating layer disposed on the data supply wire.

8. The display device of claim 3, wherein
the data transfer wire is disposed in a different layer than the data connection wire and at least partially overlaps the data connection wire.

9. The display device of claim 8, wherein
the data transfer wire is
electrically connected to the data connection wire through a contact hole defined in an insulating layer disposed on the data transfer wire.

10. The display device of claim 3, wherein
the data supply wire and the data transfer wire are arranged in a same layer.

11. The display device of claim 3, wherein
the plurality of power connection wires connect a power input wiring disposed in the second region to a power transfer wiring disposed in the first region.

12. The display device of claim 11, wherein
the power transfer wiring includes a first bending periphery disposed along a first direction corresponding to a bending axis of the substrate,
the power input wiring includes a second bending periphery disposed along the first direction,
an end of each of the plurality of power connection wires is connected to the first bending periphery, and an opposite end of each of the plurality of power connection wires is connected to the second bending periphery.

13. The display device of claim 11, wherein
the power input wiring is disposed on the data supply wire.

14. The display device of claim 11, wherein
the power transfer wiring is disposed on the data transfer wire.

15. The display device of claim 3, wherein
the data connection wire is disposed in a same layer as the plurality of power connection wires.

16. The display device of claim 15, wherein
the plurality of power connection wires and the data connection wire are arranged on a first flattening layer, and a second flattening layer is disposed on the plurality of power connection wires and the data connection wire.

17. The display device of claim 3, wherein
the data supply wire includes a first data supply wire configured to transmit a first data signal and a second data supply wire configured to transmit a second data signal.

18. The display device of claim 17, wherein
the first data supply wire and the second data supply wire are arranged in different layers from each other.

19. An electronic device comprising:
a processor;
a memory configured to store input data used by the processor or output data;
a display module configured to implement one or more images under control by the processor, the display module including:
a substrate including:
a first region including:
a display area, in which a plurality of pixels are arranged; and
a non-display area surrounding the display area;
a second region spaced from the first region and including a pad area; and
a bending region between the first region and the second region;
a plurality of data lines arranged in the display area and configured to transmit a data signal to the plurality of pixels;
a plurality of fan-out wires extending from the pad area to the display area across the bending region and respectively corresponding to the plurality of data lines; and
a plurality of power connection wires arranged across the bending region and configured to transmit power to light-emitting elements of the plurality of pixels; and
a power module configured to provide power to the processor, the memory and the display module,
wherein the plurality of fan-out wires and the plurality of power connection wires are alternately arranged in the bending region.

20. The electronic device of claim 19, wherein
each of the plurality of fan-out wires includes:
a data supply wire connected to output terminals of a display driving circuit;
a data transfer wire connected to one of the plurality of data lines of the display area; and
a data connection wire electrically connecting the data supply wire to the data transfer wire.
